(19) United States
(12) Patent Application Publication
(10) Pub. No.: US 2025/0299902 A1
(43) Pub. Date: Sep. 25, 2025

(54) SAMPLE INSPECTION SYSTEM

(71) Applicant: Hitachi High-Tech Corporation, Tokyo (JP)

(72) Inventors: Akira DOI, Tokyo (JP); Shuichi NAKAGAWA, Tokyo (JP); Masashi FUJITA, Tokyo (JP); Toshihiko SHIMIZU, Tokyo (JP); Akira NISHIOKA, Tokyo (JP); Motohiro TAKAHASHI, Tokyo (JP)

(73) Assignee: Hitachi High-Tech Corporation, Tokyo (JP)

(21) Appl. No.: 18/985,297

(22) Filed: Dec. 18, 2024

(30) Foreign Application Priority Data
Mar. 25, 2024 (JP) 2024-048643

(51) Int. Cl. H01J 37/09

(52) U.S. Cl. CPC H01J 37/09; H01J 2237/002; H01J 2237/0264; H01J 2237/26

(57) ABSTRACT

A sample inspection system includes: a charged particle beam device irradiating a sample with a charged particle beam to acquire an image of the sample; an overall control device controlling the charged particle beam device; a magnetic shield that configures an internal space for accommodating the charged particle beam device and the overall control device and blocks an external magnetic field; and an air cooling device that takes air into the magnetic shield to cool the internal space of the magnetic shield. The magnetic shield includes highly conductive material layers and high-permeability material layers, and includes an air inlet of the air for cooling in each of the highly conductive material layers and the high-permeability material layers, and a gap that is a spatial clearance is provided between the highly conductive material layer and the high-permeability material layer in a portion where the air inlet is present.

### BACKGROUND OF THE INVENTION

### 1. Field of the Invention

The present disclosure relates to a sample inspection system.

### 2. Description of Related Art

Recently, an electronic device has been rapidly developed, and a semiconductor device has become an important component configuring the electronic device. Thus far, miniaturization of the semiconductor device enables high performance and high function of the semiconductor device and contributes to the development of the electronic device. Along with the miniaturization of the semiconductor, in a semiconductor inspection device such as a scanning electron microscope (CD-SEM) that inspects a manufacturing step of the semiconductor, inspection of a circuit pattern in the order of 5 nm on a wafer has been required. Accordingly, finer measurement of the resolution of the scanning electron microscope than before has been also required. In a semiconductor factory where the scanning electron microscope is placed, a transport robot for transporting a wafer patrols the vicinity of the device, and a semiconductor etcher on which a high-output microwave source is mounted, an exposure device on which a large ultraviolet laser is mounted, or the like is placed in a location adjacent to the semiconductor factory. The scanning electron microscope is a device that inspects a fine pattern using an electron beam. Even in this environment, there is an inconvenient phenomenon in which an electron beam is affected by disturbance generated due to an external magnetic field such that an image deteriorates.

As a magnetic field that deteriorates an image, a geomagnetic direct current of about 30 μT has been targeted in the related art, but recently a high frequency direct current of several tens of kHz generated from a servomotor of the wafer transport robot along with automation has been targeted. In order to prevent the scanning electron microscope from being affected by a magnetic field in a frequency band of up to several tens of kHz generated from these direct currents, a structure that blocks the outside of the device with a magnetic shield has been considered.

In addition, when it is attempted to improve the resolution of the scanning electron microscope, a problem such as deviation in the field of view may also occur due to a temperature increase. Therefore, in order to reduce a temperature fluctuation, it is important to cool the device. As local cooling, water cooling or the like is performed. However, cooling for maintaining the entire device at a constant temperature is performed by air cooling for replacing the atmosphere in the entire device with a large amount of air. For this air cooling, an air inlet through which air passes is provided in the magnetic shield that surrounds the outside of the device.

Regarding the magnetic shield that surrounds the outside of the device, for example, JP2008-288328A discloses a magnetic shield having a multilayer structure including a highly conductive material layer and a magnetic material layer. In addition, JP-A-H08-186392 discloses a magnetic shield a honeycomb structural material is interposed between two layers of magnetic shield plates having an air inlet through which air flows as a method of providing an air inlet in a magnetic shield.

It has been learned that, since the magnetic shield includes the air inlet through which air flows, an external magnetic field penetrates into the device from the air inlet. Accordingly, it is desirable to inexpensively provide a magnetic shield where the size of a magnetic field passing through an air inlet can be reduced.

However, JP2008-288328A does not consider the influence or the like of leakage of a magnetic field from the air inlet for cooling in the magnetic shield. In addition, in the magnetic shield disclosed in JP-A-H08-186392, air flows between the inside and the outside of the magnetic shield from the air inlet. However, JP-A-H08-186392 does not describe the size of a hole, the thickness of the honeycomb structural material, materials of the two layers of the magnetic shield, and the like, does not describe the effect of reducing the size of a magnetic field passing through the air inlet, and does not clarify whether or not there is the effect of the magnetic shield.

### SUMMARY OF THE INVENTION

Under these circumstances, the present disclosure proposes a technique of minimizing the size of a magnetic field passing through an air inlet provided in a magnetic shield that blocks an external magnetic field affecting a sample inspection system.

In order to achieve the above-described object, the present disclosure proposes a sample inspection system including: a charged particle beam device that irradiates a sample with a charged particle beam to acquire an image of the sample; an overall control device that controls the charged particle beam device; a magnetic shield that configures an internal space for accommodating the charged particle beam device and the overall control device and blocks an external magnetic field; and an air cooling device that takes air into the magnetic shield to cool the internal space of the magnetic shield, in which the magnetic shield includes one or more highly conductive material layers and one or more high-permeability material layers, and the magnetic shield includes an air inlet of the air for cooling in each of the highly conductive material layers and the high-permeability material layers, and a gap that is a spatial clearance is provided between the highly conductive material layer and the high-permeability material layer in a portion where the air inlet is present.

Further characteristics related to the present disclosure will be clarified from the description of the present specification and the accompanying drawing. In addition, aspects of the present disclosure can be achieved and implemented by elements, a combination of multiple elements, the following detailed description and the scope of the appended claims.

The description of the present specification is merely a typical example and does not limit the claims or application examples of the present disclosure by any means.

According to the technique of the present disclosure, penetration of a magnetic field into the magnetic shield is reduced, and thus a clear image having a small influence of an external magnetic field on a charged particle beam can be obtained.

### BRIEF DESCRIPTION OF THE DRAWINGS

FIG. 1 is a diagram illustrating a cross-sectional configuration example of a wafer inspection device including a scanning electron microscope (charged particle beam device) according to a first embodiment of the present disclosure;

FIG. 2 is a diagram illustrating a cross-sectional configuration example of a magnetic shield 300 in the vicinity of an air inlet 305 according to the present embodiment;

FIG. 3 is a diagram illustrating a cross-sectional configuration example of the magnetic shield that is a simulated configuration of the configuration example of FIG. 2 in an experiment;

FIG. 4 is a diagram illustrating a configuration example of a magnetic field calculation system (configuration) when seen from the top;

FIG. 5 is a graph illustrating results of calculating a magnetic field generated from a magnetic field calculation point while changing only a frequency at a fixed amplitude of a current flowing through a magnetic field generation coil;

FIG. 6 is a graph illustrating a state where a hole diameter of the air inlet and the size of a gap affects a magnetic field passing through the air inlet;

FIG. 7 is a diagram illustrating a cross-sectional configuration example of a magnetic shield (Comparative Example) 300′ formed using a well-known technique;

FIG. 8 is a diagram illustrating a cross-sectional configuration example of a magnetic shield 300 for a scanning electron microscope according to a second embodiment of the present disclosure;

FIG. 9 is a diagram illustrating a cross-sectional configuration example of a magnetic shield 300 for a scanning electron microscope according to a third embodiment of the present disclosure; and

FIG. 10 is a diagram illustrating a cross-sectional configuration example of a magnetic shield 300 for a scanning electron microscope according to a fourth embodiment of the present disclosure.

### DESCRIPTION OF EMBODIMENTS

An embodiment of the present disclosure relates to a magnetic shield for accommodating a charged particle beam device (scanning electron microscope) that configures a sample inspection system (semiconductor inspection system) for inspecting a sample (wafer) used in an electronic device and a computer that controls the charged particle beam device. More specifically, the present embodiment relates to a magnetic shield including: a first magnetic shield portion including a plurality of air inlets and a second magnetic shield portion not including an air inlet, in which a gap is provided between a highly conductive material layer and a high-permeability material layer configuring the first magnetic shield portion.

Hereinafter, each of embodiments and each of examples of the present disclosure will be described with reference to the accompanying drawings. In the accompanying drawings, functionally the same elements may also be represented by the same reference numerals. The accompanying drawings illustrate specific embodiments and implementations based on the principle of the present disclosure. These drawings are examples for easy understanding of the present disclosure and are not used to limit the present disclosure.

In the present embodiment, the present disclosure is described in detail sufficient for a person skilled in the art to implement the present disclosure, but other embodiments and configurations can also be adopted. It should be understood that changes of configurations and structures and replacement of various elements can be made within a range not departing from the scope and concepts of the technical idea of the present disclosure. Accordingly, the following description should not be interpreted as being limited to the present disclosure.

### FIRST EMBODIMENT

### (i) Configuration Example of Wafer Inspection Device

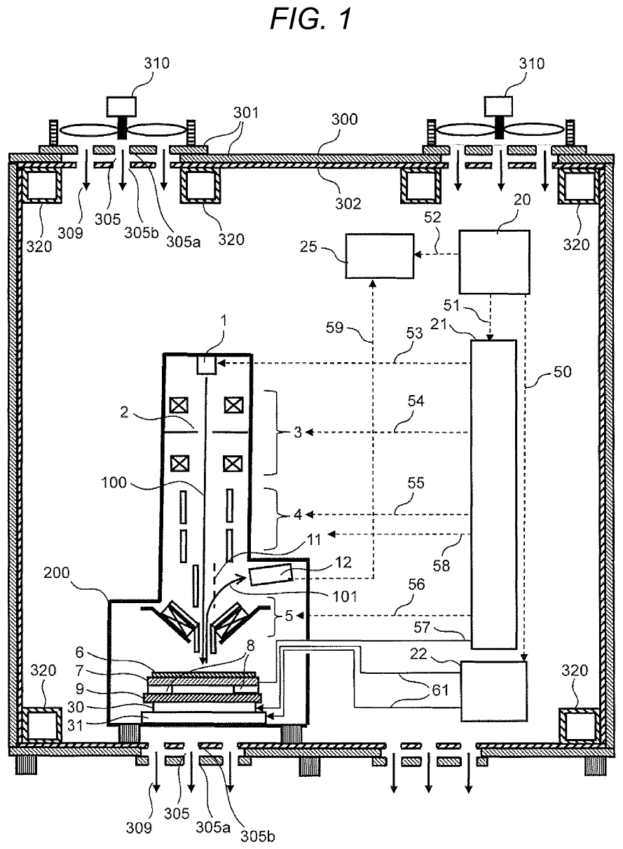

FIG. 1 is a diagram illustrating a cross-sectional configuration example of a wafer inspection device including a scanning electron microscope (charged particle beam device) according to a first embodiment of the present disclosure. In the present embodiment, a scanning electron microscope will be described. However, even in other inspection devices that are affected by a magnetic field, for example, a length-measuring scanning electron microscope, a scanning electron microscope with a defect review function, the same effect can be obtained.

In FIG. 1, a primary electron beam (charged particle beam) 100 formed in an electron gun 1 forms a fine beam using a condenser lens 3 and an aperture 2. The formed beam is deflected by a scanning deflector 4 and is focused by an objective lens 5 to irradiate a surface of a wafer 6 as an observation target with the focused beam. On the wafer surface, a holder voltage (negative voltage) 57 is applied (to facilitate emission of secondary electrons) to a holder 7 such that secondary electrons 101 are emitted. The secondary electrons are deflected by a deflector 11 for extracting secondary electrons to be input to a detector 12. The detector 12 converts the secondary electrons into an electric signal, and supplies the electric signal as detector data 59 to an image acquisition device 25 to generate an image.

An overall control device 20 that controls the overall device supplies an optical system instruction 51 that is a setting condition of an optical system to an optical system control device 21. Based on an instruction value of the optical system instruction 51, the optical system control device 21 inputs an electron gun instruction 53 to the electron gun 1, inputs a condenser lens instruction 54 to the condenser lens 3, inputs a scanning deflector instruction 55 to the scanning deflector 4, inputs an objective lens instruction 56 to the objective lens 5, and inputs the holder voltage 57 to the holder 7. A table 9 is provided in the uppermost portion of a stage (an X stage 30 and a Y stage 31). On the table 9, the holder 7 on which the wafer 6 is mounted is applied with a negative voltage and is provided with an electrically insulating portion 8 interposed therebetween.

The stage that moves a position of the wafer 6 is placed in a vacuum container 200 positioned below a device optical system. As the stage, a multi-axis stage that is movable in translation directions of at least two axes is mounted. In the present embodiment, a stage 30 (X-axis direction) and a stage 31 (Y-axis direction) of two axes in a horizontal direction are provided. In addition to the X stage 30 and the Y stage 31, a Z stage that moves the wafer 6 in a Z direction (up-down direction in FIG. 1) may be provided.

The overall control device 20 supplies a stage position instruction 50 such as target position information of each of the stages to a stage control device 22. Based on an instruction value of the stage position instruction 50, the stage control device 22 supplies a stage driving current 61 for driving each of the stages to the stages of the two axes to control a position of the table.

In the scanning electron microscope, particularly a trajectory of an electron beam is bent when a magnetic field is externally applied. Therefore, an image deteriorates due to the magnetic field from the outside of the device. Further, even in the other control systems, an image deteriorates due to an electromagnetic noise such as a magnetic field or an electric field generated by an alternating magnetic field. In order to prevent this deterioration, in the present embodiment, the magnetic shield 300 for shielding an outer peripheral portion of the device from magnetism is provided. The magnetic shield 300 is configured with two or more layers including a highly conductive material layer 301 that is formed of an aluminum or copper alloy on the outside and a high-permeability material layer 302 that is formed of Permalloy or pure iron on the inside. In the present embodiment, an example of the two-layer configuration including one highly conductive material layer 301 and one high-permeability material layer 302 will be described. However, in order to further reduce the size of a magnetic field penetrating the inside, multiple layers may be provided. Note that it is important that the outermost layer is the highly conductive material layer 301 from the viewpoint of reducing a high frequency magnetic field. The reason for this is as follows. In a case where an alternating magnetic field penetrates from the outside of the device, when the outermost layer is formed of a highly conductive material, an effect of reflecting the alternating magnetic field due to the flow of an eddy current can be obtained. On the other hand, when the outermost layer is formed of a high-permeability material, an effect of absorbing the magnetic field can be obtained, and thus the size of the magnetic field passing through the magnetic shield increases. In the case of a direct current magnetic field, the highly conductive material does not have an effect of blocking the magnetic field, and thus the effect does not change depending on whether the outermost layer is formed of the highly conductive material or the high-permeability material.

A plurality of air inlets 305 through which air flows are provided in an upper portion and a lower portion of the magnetic shield 300. The air inlet 305 is configured such that an air inlet 305a present in the highly conductive material layer 301 and an air inlet 305b present in the high-permeability material layer 302 are provided to face each other. Air 309 flows between the air inlet 305a and the air inlet 305b in a direction indicated by arrow. In order to compulsorily cause air to flow at a high flow rate, a ventilation unit 310 is provided above the air inlet 305 in the upper portion of the device. The highly conductive material layer 301 and the high-permeability material layer 302 are fixed to a rigid frame 320 such as stainless steel (the frame is configured with a plurality of sub-frames provided in a direction perpendicular to the paper plane and a direction parallel to the paper plane in FIG. 1) through a bolt.

In the present embodiment, the air 309 forms a downflow from the upper side to the lower side. When a ventilation direction of the ventilation unit 310 is reversed, the air can also be ventilated from the lower side to the upper side. In addition, regarding the position of the air inlet 305, the air inlet 305 can also be in a left portion and a right portion of the device instead of the upper portion and the lower portion to ventilate the air in the horizontal direction.

In the magnetic shield 300, a hole or the like for transporting a wafer to be inspected is also present in addition to the air inlet 305. However, the ratio of the total area of the air inlet is the largest, and one issue is to prevent penetration of a magnetic field into the magnetic shield 300 through this hole. Hereinafter, in the present embodiment, a method of suppressing the penetration of a magnetic field into the magnetic shield 300 through the air inlet 305 will be described.

### (ii) Configuration Example of Magnetic Shield 300

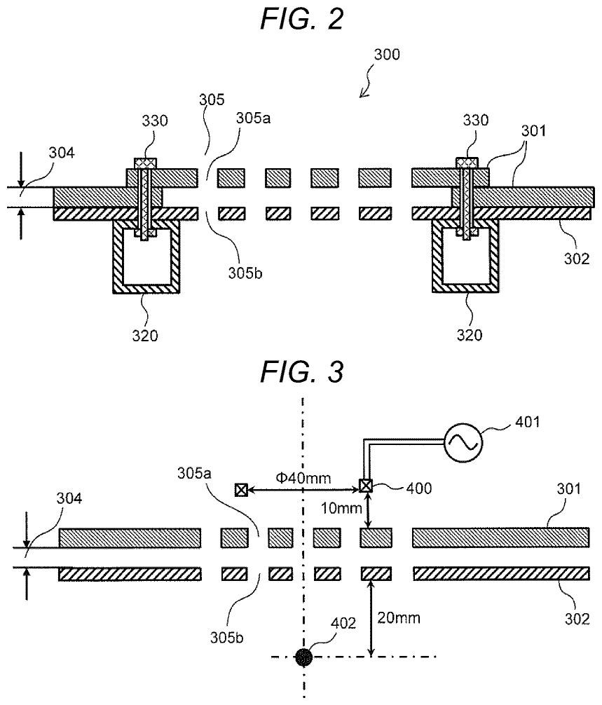

FIG. 2 is a diagram illustrating a cross-sectional configuration example of the magnetic shield 300 in the vicinity of an air inlet 305 according to the present embodiment. The outside of the magnetic shield 300 is configured with the highly conductive material layer 301 and includes the air inlet 305a. The inside of the magnetic shield 300 is configured with the high-permeability material layer 302 and includes the air inlet 305b. Here, the characteristic feature of the present embodiment is that only a portion of the highly conductive material layer 301 where the air inlet 305a is provided is configured with a separate plate (separate member), the high-permeability material layer 302 and a gap 304 are provided only in this portion, and each of the layers is fixed to the frame 320 through a bolt 330 in this state. The gap may be configured by configuring only a portion of the high-permeability material layer 302 where the air inlet 305b is provided with a separate plate (separate member), disposing this portion below the high-permeability material layer 302 where the air inlet 305b is not provided, and fixing each of the layers to the frame 320 through the bolt 330. In addition, the thickness of the highly conductive material layer 301 and the thickness of the high-permeability material layer 302 may be the same as or different from each other. For example, the highly conductive material layer 301 may be configured to be thicker than the high-permeability material layer 302, or the high-permeability material layer 302 can also be configured to be thicker than the highly conductive material layer 301.

### (iii) Discussion on Optimum Size of Gap 304

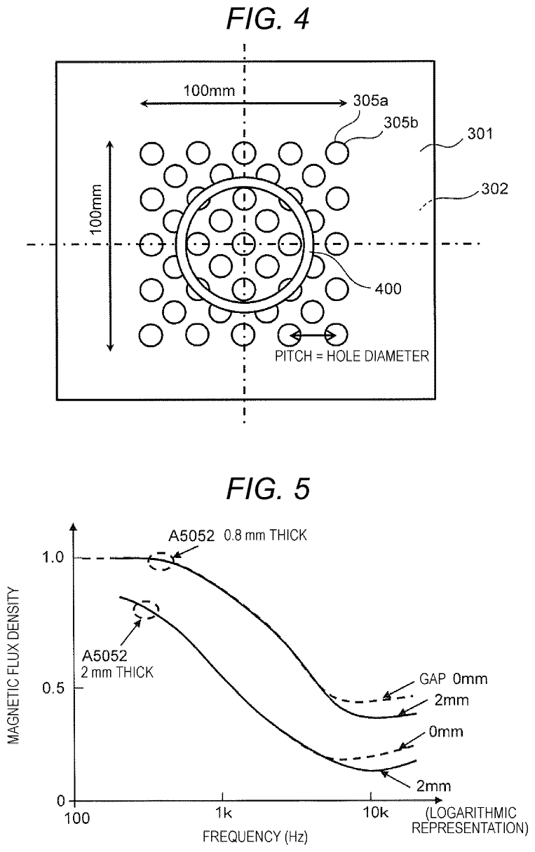

In order to optimize the size of the gap 304, magnetic field calculation (experiment) is performed as follows. A system using the magnetic field calculation (configuration used in the experiment) will be described using FIGS. 3 and 4. FIG. 3 is a diagram illustrating a cross-sectional configuration example of the magnetic shield that is a simulated configuration of the configuration example of FIG. 2 in the experiment. In FIG. 3, the upper layer is the highly conductive material layer 301, and A5052 that is an aluminum alloy is used in the calculation (experiment). The lower layer is the high-permeability material layer 302, and Permalloy PC is used. The highly conductive material layer 301 includes the air inlet 305a. The high-permeability material layer 302 includes the air inlet 305b. It is assumed that both of the air inlets 305a and 305b have the same diameter. The gap 304 is provided between the highly conductive material layer 301 and the high-permeability material layer 302. A magnetic field generation coil 400 having a diameter of 40 mm is placed 10 mm above the highly conductive material layer 301.

In addition, a frequency-variable alternating current power supply 401 for causing a current to flow through the magnetic field generation coil 400 is connected to the magnetic field generation coil 400. A position on the central axis of the magnetic field generation coil 400 that is present 20 mm below the high-permeability material layer 302 is set as a magnetic field calculation point 402, a magnetic field at this position is calculated, and the size of a magnetic field passing through the air inlet is estimated by the calculation.

FIG. 4 is a diagram illustrating a configuration example of the magnetic field calculation system (configuration) when seen from the top. The air inlet 305a in the highly conductive material layer 301 and the air inlet 305b in the high-permeability material layer 302 have the same diameter, and are disposed at the same position (the centers of the air inlets match with each other) when seen from the top. In addition, a pitch between the hole and the hole (distance between the centers of the air inlets) is set to be two times of the hole diameter of the air inlet. Further, the air inlet is disposed to fill a 100 mm×100 mm region.

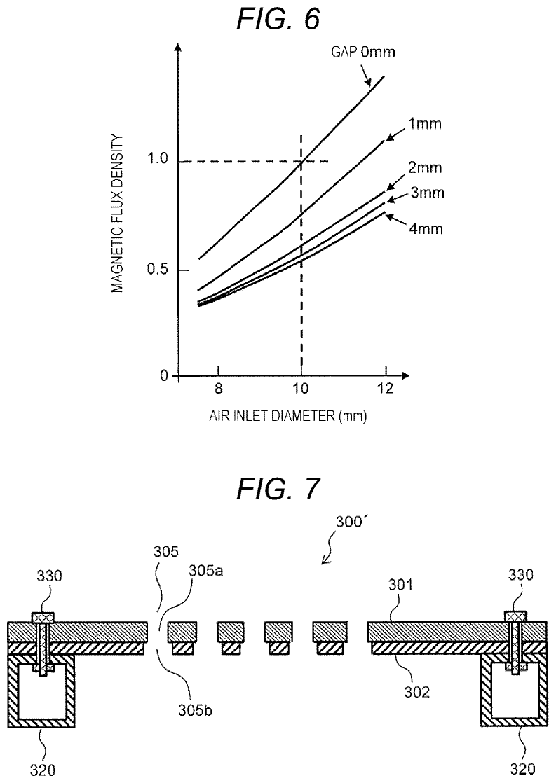

Hereinafter, the results of evaluating the magnetic field passing through the air inlet in the system described in FIGS. 3 and 4 will be described with reference to FIGS. 5 and 6.

FIG. 5 is a graph illustrating results of calculating a magnetic field generated from a magnetic field calculation point while changing only a frequency at a fixed amplitude of a current flowing through a magnetic field generation coil. In the graph of FIG. 5, the horizontal axis represents a logarithmic representation of the frequency (log₁₀ frequency), and the vertical axis represents the amplitude of the calculated magnetic flux density. Here, as the system (configuration) of the magnetic shield 300 for the magnetic field calculation, a configuration where the thickness of Permalloy PC of the high-permeability material layer 302 is set to 0.8 mm, the thickness of A5052 of the highly conductive material layer 301 is set to 0.8 mm or 2mm, and the gap is set to 0 mm or 2 mm is adopted.

As a result, it was found that, when the thickness of A5052is 2 mm, the magnetic field passing through the air inlet can be reduced at all the frequencies as compared to a case where the thickness of A5052 is 0.8 mm. This phenomenon is derived from the fact that, as the thickness of A5052 is thicker, the magnetic field passing through the air inlet attenuates, which is well-known. In addition, it was found that, from about the frequency (logarithmic representation) exceeding 5 kHz, the magnetic field passing through the air inlet when the gap is 2 mm can also be further reduced as compared to a case where the gap is 0 mm. The skin depth of A5052 is about 1.1 mm at a resistivity of 4.9×10⁻⁸ Ωm and 10 kHz. FIG. 5 illustrates the results of the case where the thickness of A5052 is 0.8 mm and the case where the thickness of A5052 is 2 mm. According to the results, a magnetic field does not substantially pass through A5052 at 10 kHz, and it is considered the magnetic field passing through the air inlet (diameter: 10 mm) is predominant. That is, the reason for this is presumed to be as follows. When the frequency is high, a magnetic field passes through only the air inlet, and when the frequency is low, a magnetic field passes through a hole other than the air inlet (hole). Therefore, when the gap increases at a high frequency of 5 KHZ or higher, the magnetic field passing through only the air inlet 305a of the highly conductive material layer 301 spreads before arriving at the air inlet 305b of the high-permeability material layer 302, and the attenuation phenomenon occurs.

FIG. 6 is a graph illustrating a state where a hole diameter of the air inlet and the size of the gap affects the magnetic field passing through the air inlet. In the graph of FIG. 6, the horizontal axis represents the diameter of the air inlet, and the vertical axis represents the intensity of the magnetic field passing through the air inlet. In the drawing, the size of the magnetic field passing through the air inlet is normalized by the air inlet diameter of 10 mm and the gap size of 0 mm. It can be seen from FIG. 6 that, by increasing the size of the gap to, for example, 0 mm, 1 mm, 2 mm, 3 mm, or 4 mm, the magnetic field passing through the air inlet decreases as the size of the gap increases. Note that, based on the results of increasing the gap size from 2 mm to 4 mm, even when the gap size is ⅓ or more of the air inlet diameter, there is no significant change on the effect (to some extent, the attenuation of the magnetic field increases). However, for example, when the gap size needs to be set to be large due to the device configuration, it is meaningful to set the size of the gap to be ⅓ or more of the air inlet diameter. As described above, it can be seen based on the graph of FIG. 6 that the size of the gap needs to be 1/10 or more of the air inlet diameter.

Based on the above-described finding, in the present embodiment, the size of the magnetic field passing through the air inlet 305 can be reduced by setting the size of the gap 304 in FIG. 2 to be 1/10 or more of the hole diameter of the air inlet 305.

### (iv) Comparison between Present Embodiment and Comparative Example

Finally, a case where a magnetic shield is formed using a well-known technique (Comparative Example) and the present embodiment are compared to each other.

FIG. 7 is a diagram illustrating a cross-sectional configuration example of a magnetic shield (Comparative Example) 300′ formed using a well-known technique. The cross-sectional configuration example of the magnetic shield 300′ according to Comparative Example and the cross-sectional configuration example of the magnetic shield 300 according to the present embodiment are different in that, in Comparative Example, one highly conductive material layer 301 and one high-permeability material layer 302 are prepared and the air inlet 305a and the air inlet 305b are provided in each of the layers and that a gap is not present between the highly conductive material layer 301 and the high-permeability material layer 302.

In a case where a gap is not present in the magnetic shield 300′, when the positions of the air inlet 305a and the air inlet 305b largely deviate from each other, the cross-sectional area where air flows decreases such that air is not likely to flow. In order to prevent this phenomenon, it is necessary to increase the diameter of the air inlet on the single side such that, even when the positions of the air inlet 305a and the air inlet 305b deviate from each other, the total cross-sectional area of the air inlet is not small. In Comparative example of FIG. 7, the diameter of the air inlet 305b of the high-permeability material layer 302 is larger than that of the air inlet 305a. This way, by increasing the diameter of the air inlet, the size of the magnetic field passing through the air inlet increases.

In addition, it is effective to form the highly conductive material layer 301 using aluminum from the viewpoint of the cost, but aluminum is a soft material. Therefore, punching is generally used for forming a plurality of holes such as the air inlet. However, when punching is used, a plate may be warped. Therefore, in order to correct the warpage after the punching, a step such as rolling is performed, which deteriorates the position accuracy of the holes. Therefore, it is difficult to make the positions of the air inlet 305a and the air inlet 305b match with each other. On the other hand, in the present embodiment, the gap 304 is provided between the air inlet 305a and the air inlet 305b as illustrated in FIG. 2. Therefore, even when the positions of the air inlet 305a and the air inlet 305b deviate from each other, the cross-sectional area where air flows does not decrease, and the diameters of the air inlet 305a and the air inlet 305b can be made the same.

Further, in the present embodiment, as illustrated in FIG. 2, the portion of the highly conductive material layer 301 where the air inlet 305a is provided has the structure where two highly conductive material layers 301 are fixed to the frame 320 through the bolt to increase the rigidity of the air inlet portion having a weak structural strength. As compared to the present embodiment, the magnetic shield 300′ in the well-known technique (Comparative Example) of FIG. 7 has the structure where the rigidity in the vicinity of the air inlet 305 is weak. In order to increase the rigidity, the highly conductive material layer 301 can be configured to be thicker than a plate thickness of the high-permeability material layer 302. However, when punching is used for forming the holes, the plate thickness is limited. For example, in the case of aluminum, only a plate having a thickness of about 3 mm or less can be processed with punching, and in the case of a hard material such as Permalloy or stainless steel, only a plate having a thickness of less than 3 mm can be processed with punching. In addition, when the plate thickness is large as a whole, there is an inconvenience in terms of weight or cost, and it can be said that the present embodiment is excellent in terms of weight, cost, and rigidity.

### SECOND EMBODIMENT

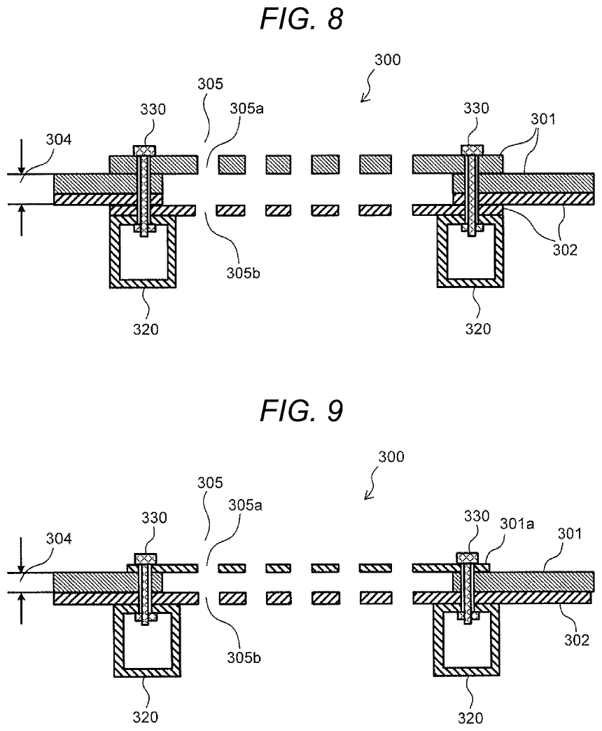

FIG. 8 is a diagram illustrating a cross-sectional configuration example of a magnetic shield 300 for a scanning electron microscope according to a second embodiment of the present disclosure. In FIG. 8, components represented by reference numerals 1 to 330 are the same as those of FIG. 2.

The second embodiment is different from the first embodiment (FIG. 2) in that the portion of the high-permeability material layer 302 where the air inlet 305b is provided is a component that is provided separately from the other portions. A step of forming a plurality of holes in a large plate is difficult, and the cost is also required. Therefore, it is preferable to separately provide a portion where many holes are formed as in the air inlet. Further, in this structure, the gap 304 is the total thickness of the highly conductive material layer 301 and the high-permeability material layer 302. Therefore, this structure is effective for increasing the gap.

### THIRD EMBODIMENT

FIG. 9 is a diagram illustrating a cross-sectional configuration example of a magnetic shield 300 for a scanning electron microscope according to a third embodiment of the present disclosure. In FIG. 9, components represented by reference numerals 1 to 330 are the same as those of FIG. 2.

The third embodiment is different from the first embodiment (FIG. 2) in that a material and a plate thickness of a portion of the highly conductive material layer 301 where the air inlet 305a is not provided are different from those of a portion of a highly conductive material layer 301a where the air inlet 305a is provided.

In the third embodiment, the highly conductive material layer 301 is formed of a duralumin-based material such as A5052 that is an aluminum alloy, copper, or a copper alloy as a material having excellent cost, rigidity, and conductivity.

On the other hand, the highly conductive material layer 301a is directly joined to the frame 320 through the bolt 330, and thus the rigidity is not that important. Therefore, as the material, a material such as pure aluminum or copper having a high conductivity but a poor Young's modulus can be selected. In addition, the highly conductive material layer 301a can be formed of a material having a high conductivity. Therefore, the plate thickness can also be reduced as necessary. When the highly conductive material layer 301a is formed of copper, copper has rigidity that is two times or more of that of aluminum. Therefore, the plate thickness of the highly conductive material layer 301a can be reduced to half or less of that when the highly conductive material layer 301a is formed of aluminum.

In FIG. 9, the thickness of the highly conductive material layer 301a of the portion where the air inlet 305a is provided is less than the thickness of the highly conductive material layer 301 of the portion where the air inlet 305a is not provided. However, the third embodiment is not limited to this example. For example, the thickness of the highly conductive material layer 301a of the portion where the air inlet 305a is provided may be larger than the thickness of the highly conductive material layer 301 of the portion where the air inlet 305a is not provided. In addition, the thicknesses of both of the highly conductive material layer 301a of the portion where the air inlet 305a is provided and the high-permeability material layer 302 of the portion where the air inlet 305b is provided may be less than the thicknesses of both of the highly conductive material layer 301 of the portion where the air inlet 305a is not provided and the high-permeability material layer 302 of the portion where the air inlet 305b is not provided.

### FOURTH EMBODIMENT

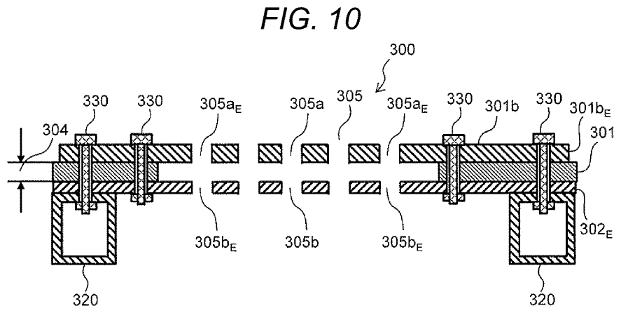

FIG. 10 is a diagram illustrating a cross-sectional configuration example of a magnetic shield 300 for a scanning electron microscope according to a fourth embodiment of the present disclosure. In FIG. 10, components represented by reference numerals 1 to 330 are the same as those of FIG. 2.

The fourth embodiment is different from the third embodiment (FIG. 9) in that, in the fourth embodiment, the frame 320 is not present in the vicinity of the air inlet 305 and is present at a position slightly distant from the air inlet 305 and that a highly conductive material layer 301b of the portion where the air inlet 305a is provided is widely disposed to arrive at the frame 320 such that the highly conductive material layer 301b is directly joined to the frame 320. More specifically, the highly conductive material layer 301b where the air inlet 305a is provided and the high-permeability material layer 302 where the air inlet 305b is provided can be configured such that distances from an air inlet 305a_{E} and an air inlet 305b_{E} in an end portion to a highly conductive material layer end 301b_{E} and a high-permeability material layer end 302_{E} (the width of a peripheral region for fixing the highly conductive material layer 301b and the high-permeability material layer 302 to the frame 320 through the bolt) are two times or more of a distance in a transverse direction of the sub-frames configuring the frame 320.

In the fourth embodiment, since the rigidity is important, the highly conductive material layer 301b is formed of a material that can ensure rigidity, for example, copper, a copper alloy, or duralumin having high conductivity and rigidity.

The configuration of the fourth embodiment is applicable to a case where the air inlet 305 is disposed in a portion where the frame 320 cannot be provided due to a fan or the like provided in the vicinity of the air inlet 305.

What is claimed is:

1. A sample inspection system comprising:
a charged particle beam device that irradiates a sample with a charged particle beam to acquire an image of the sample;
an overall control device that controls the charged particle beam device;
a magnetic shield that configures an internal space for accommodating the charged particle beam device and the overall control device and blocks an external magnetic field; and
an air cooling device that takes air into the magnetic shield to cool the internal space of the magnetic shield,
wherein the magnetic shield includes one or more highly conductive material layers and one or more high-permeability material layers, and
the magnetic shield includes an air inlet of the air for cooling in each of the highly conductive material layers and the high-permeability material layers, and a gap that is a spatial clearance is provided between the highly conductive material layer and the high-permeability material layer in a portion where the air inlet is present.

2. The sample inspection system according to claim 1, wherein the gap is provided with a size that is 1/10 or more of a diameter of the air inlet.

3. The sample inspection system according to claim 1,
wherein the magnetic shield includes a first magnetic shield portion having the air inlet and a second magnetic shield portion not having the air inlet,
the first magnetic shield portion and the second magnetic shield portion are configured independently of each other, and
the first magnetic shield portion is attached to at least one of a position above the highly conductive material layer configuring the second magnetic shield portion or a position below the high-permeability material layer configuring the second magnetic shield portion to form the gap.

4. The sample inspection system according to claim 3,
wherein the highly conductive material layer is configured to be thicker than the high-permeability material layer in the first magnetic shield portion and the second magnetic shield portion.

5. The sample inspection system according to claim 3,
wherein a material of the first magnetic shield portion is different from a material of the second magnetic shield portion.

6. The sample inspection system according to claim 5,
wherein the second magnetic shield portion is formed of a material having a higher rigidity than the first magnetic shield portion.

7. The sample inspection system according to claim 1,
wherein the magnetic shield includes a first magnetic shield portion having the air inlet and a second magnetic shield portion not having the air inlet,
the first magnetic shield portion and the second magnetic shield portion are configured independently of each other, and a thickness and a material of the highly conductive material layer in the first magnetic shield portion are different from a thickness and a material of the highly conductive material layer in the second magnetic shield portion.

8. The sample inspection system according to claim 1,
wherein the magnetic shield includes a first magnetic shield portion having the air inlet and a second magnetic shield portion not having the air inlet,
the first magnetic shield portion and the second magnetic shield portion are configured independently of each other, and a thickness and a material of the high-permeability material layer in the first magnetic shield portion are different from a thickness and a material of the high-permeability material layer in the second magnetic shield portion.

9. The sample inspection system according to claim 1,
wherein the magnetic shield includes a first magnetic shield portion having the air inlet and a second magnetic shield portion not having the air inlet,
the highly conductive material layer and the high-permeability material layer of the magnetic shield are fixed to a frame configured with a plurality of sub-frames to configure the internal space for accommodating the charged particle beam device and the overall control device,
a distance between the two sub-frames adjacent to each other in the frame is longer than a length between the air inlets closest to an end portion of the first magnetic shield portion,
the first magnetic shield portion includes an air inlet formation region where a plurality of the air inlets are provided and a peripheral region where the air inlet is not provided, and
the first magnetic shield portion is fixed to the sub-frames and the second magnetic shield portion in the peripheral region.

10. The sample inspection system according to claim 9,
wherein in the peripheral region in the first magnetic shield portion, a distance from an end of the air inlet closest to the end portion of the first magnetic shield portion to an end of the peripheral region is larger than two times of a distance in a transverse direction of the sub-frames.

11. The sample inspection system according to claim 10,
wherein the highly conductive material layer and the high-permeability material layer in the first magnetic shield portion are formed of copper, a copper alloy, or duralumin, and
a thickness of the highly conductive material layer in the first magnetic shield portion is substantially the same as a thickness of the highly conductive material layer in the second magnetic shield portion.
